(19) United States
(12) Patent Application Publication
(10) Pub. No.: US 2007/0178943 A1
(43) Pub. Date: Aug. 2, 2007

(54) Circuit board for mobile communication terminal having ultrasonic wave speaker system

(76) Inventor: Kyungmin Na, Seoul (KR)

Correspondence Address: CANTOR COLBURN, LLP, 55 GRIFFIN ROAD SOUTH, BLOOMFIELD, CT, 06002, US

(21) Appl. No.: 10/591,010

(22) PCT Filed: Mar. 30, 2005
(86) PCT No.: PCT/KR05/00925

§ 371 Date: Aug. 29, 2006

(30) Foreign Application Priority Data
Apr. 2, 2004 (KR) 10-2004-0009176

(51) Int. Cl. H04M 1/00; H05K 11/00

(52) U.S. Cl. 455/569.1; 455/344

(57) ABSTRACT

Disclosed is a mobile communication terminal board having an ultrasonic speaker system which can be used without any separate additional device during a viewing of a sky-wave broadcast or during a video calling and which can be free from an echo phenomenon. The mobile communication terminal board includes a baseband chip for processing audio data, an ultrasonic drive chip for receiving and modulating a signal output from the baseband chip to an ultrasonic band signal, and an ultrasonic speaker for outputting the ultrasonic signal output from the ultrasonic drive chip to an outside.

### TECHNICAL FIELD

The present invention relates generally to a mobile communication terminal, and more particularly to a mobile communication terminal board having an ultrasonic speaker system.

### BACKGROUND ART

Recently, with the abrupt development of information society, the development of a combined communication terminal having diverse additional functions in addition to a simple function of voice transmission is required.

In compliance with this requirement, a mobile communication terminal (so called, a “camera phone”) has been developed. Since this mobile communication terminal has a digital camera function in addition to the same voice call function as the conventional mobile communication terminal, it can transmit by wireless an image taken by the digital camera to another terminal, and also can output the image through a display screen of a PC (Personal Computer) or store the image in a storage device provided in the PC in a state that the mobile communication terminal is connected to the PC.

Additionally, a mobile communication terminal that can receive a sky-wave broadcasting program, a mobile communication terminal that can connect to the Internet and download Internet information and a mobile communication terminal that can display a moving image have been developed.

Consequently, in conformity with a multimedia era, a next-generation mobile communication terminal (IMT-2000) that can perform all the above-described functions including the voice transmission/reception function and the image transmission/reception function has been developed.

Meanwhile, in the case of making a video call using such a mobile communication terminal, a user should keep a specified distance from the terminal in order for the user to transmit the user's image and to speak by phone as he/she is confirming the received image of an opposite party. For this, a wire/wireless earset or headset should be connected to the mobile communication terminal, or a speaker phone function should be provided in the mobile communication terminal.

However, the use of such a wire/wireless earset or headset causes inconvenience to the user.

Additionally, in the case of using the speaker phone function, sound generated from the speaker, which has a structure that generates the sound by vibrating a vibrating plate, spreads in all directions, and this causes a noise around the terminal and an exposure of the user's private life. Also, due to an echo generated as the sound output through the speaker is reflected and input to a microphone of the terminal, it is difficult in technique to implement a high-performance speaker phone.

### DISCLOSURE OF THE INVENTION

Technical Problem

Therefore, the present invention has been made in view of the above-mentioned problems, and it is an object of the present invention to provide a mobile communication terminal board having an ultrasonic speaker system which can be used without any separate additional device during the viewing of a sky-wave broadcast or during a video calling and which can be free from the echo phenomenon.

Technical Solution

According to an aspect of the present invention, there is provided a mobile communication terminal board comprising a baseband chip for processing audio data, an ultrasonic drive chip for receiving and modulating a signal output from the baseband chip to an ultrasonic band signal, and an ultrasonic speaker for outputting the ultrasonic signal output from the ultrasonic drive chip to an outside.

In another aspect of the present invention, there is provided a mobile communication terminal board comprising an ultrasonic speaker for outputting a signal modulated to an ultrasonic band, and a baseband chip, integratedly provided with an ultrasonic drive chip for driving the ultrasonic speaker, for controlling a driving of the mobile communication terminal.

In the present invention, an ultrasonic speaker system is used in the mobile communication terminal, and an audible sound field is formed within a desired area by modulating the output signal to the ultrasonic band signal. Accordingly, the present invention can solve the problems involved in the prior art that causes the noise around the terminal and an invasion of the user's private life due to the spread of the sound generated from the speaker in all directions.

### BRIEF DESCRIPTION OF THE DRAWINGS

The foregoing and other objects, features and advantages of the present invention will become more apparent from the following detailed description when taken in conjunction with the accompanying drawings in which:

FIG. 1 is a view illustrating the construction of a mobile communication terminal board having an ultrasonic micro speaker according to a first embodiment of the present invention;

FIG. 2 is a block diagram illustrating the internal construction of an ultrasonic drive chip of FIG. 1 to which an ultrasonic speaker for outputting a corresponding output signal of the ultrasonic drive chip is attached;

FIG. 3 is a perspective view of an ultrasonic speaker and an ultrasonic drive chip that are implemented as a module;

FIG. 4 is a view schematically illustrating the internal construction of an ultrasonic drive circuit board of FIG. 3;

FIG. 5 is a conceptual view illustrating the construction of a mobile communication terminal board having an ultrasonic micro speaker and a baseband chip having a drive circuit for driving the speaker according to a second embodiment of the present invention;

FIG. 6 is a view illustrating the ultrasonic drive chip and the ultrasonic speaker integrated into a semiconductor chip;

FIG. 7 is a conceptual view illustrating the structure of the ultrasonic speaker of FIGS. 1 to 5 implemented as a piezoelectric element;

FIG. 8 is a view illustrating the structure of the ultrasonic speaker of FIGS. 1 to 5 implemented as a thin film type; and

FIG. 9 is a view illustrating the ultrasonic speaker of FIGS. 1 to 5 implemented using an MEMS technique.

### BEST MODE FOR CARRYING OUT THE INVENTION

Reference will now be made in detail to the preferred embodiments of the present invention.

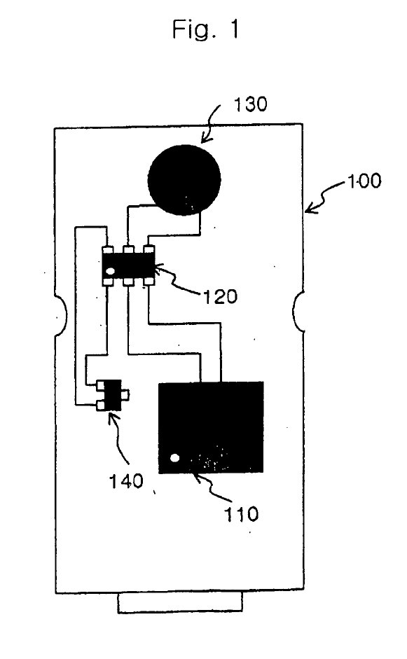

FIG. 1 is a view illustrating the construction of a mobile communication terminal board having an ultrasonic micro speaker according to a first embodiment of the present invention.

Referring to -FIG. 1, a mobile communication terminal board, i.e., a mobile communication terminal printed circuit board (PCB) 100 includes a baseband chip 110 for outputting a signal, an ultrasonic drive chip 120 for receiving and modulating the signal output from the baseband chip 110 to an ultrasonic band signal, an ultrasonic speaker 130 for outputting the ultrasonic signal output from the ultrasonic drive chip 120 to an outside, and a power supply unit 140 for providing a power to the ultrasonic drive chip 120.

In the case in which a user makes a phone call with the mobile communication terminal in the user's hand, it is natural to speak over the phone if an audible sound field is formed in a user's face region within the range of 40 to 60 cm. Accordingly, it is preferable that the ultrasonic drive chip 120 is designed to provide an audio output of about 60 dB in a distance of about 40 to 60 cm.

In operation, the signal output through the baseband chip 110 is modulated to the ultrasonic band signal by the ultrasonic drive chip 120, and then output through the ultrasonic speaker 130. The ultrasonic band signal output from the ultrasonic speaker is demodulated to the original audible signal that has a straightness and directionality by a nonlinearity of air, so that only the user can hear the demodulated audio signal.

In the present invention, since the output ultrasonic band signal is not audible outside the audible sound field formed by the ultrasonic signal, noise around the terminal or an invasion of the user's private life can be prevented. Additionally, since no separate additional device is required and no signal is fed back, it is possible to implement an echoless high-performance speaker phone.

Now, the internal constituent blocks and the operation of the ultrasonic drive chip 120 that receives and modulates the output signal of the baseband chip 110 to the ultrasonic band signal will be explained in detail.

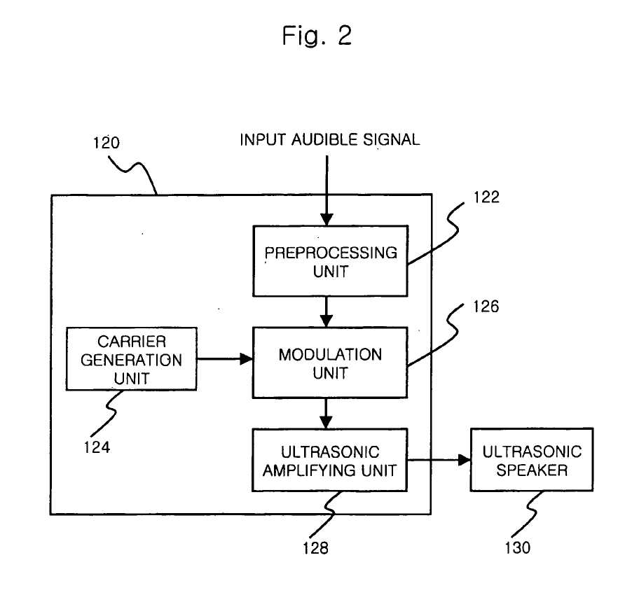

FIG. 2 is a block diagram illustrating the internal construction of an ultrasonic drive chip 120 of FIG. 1 to which an ultrasonic speaker 130 for outputting the corresponding output signal of the ultrasonic drive chip is attached.

Referring to FIG. 2, the ultrasonic drive chip 120 includes a preprocessing unit 122 for receiving an audible signal such as music, sound, etc., and performing a band compensation, distortion compensation, etc., of the received signal, a carrier generation unit 124 for generating a carrier of an ultrasonic band, a modulation unit 126 for modulating an output signal of the preprocessing unit 122 to the ultrasonic band signal using the carrier, and an ultrasonic amplifying unit 128 for amplifying an output signal of the modulation unit 126.

Additionally, the ultrasonic speaker 130 outputs the ultrasonic signal output from the ultrasonic amplifying unit 128 in the ultrasonic drive chip 120.

In operation, the audible signal such as music, sound, etc., input from a signal source is preprocessed by the preprocessing unit 122. The preprocess operation includes a band compensation, distortion compensation, etc. Then, the preprocessed signal is modulated to the ultrasonic band signal by the modulation unit 126 using the ultrasonic carrier generated from the carrier generation unit 124. This ultrasonic band signal is amplified by the ultrasonic amplifying unit 128, and then radiated to air through the ultrasonic speaker 130.

For reference, it is preferable that the ultrasonic drive chip 120 is designed to provide an audio output of about 60 dB within a distance of about 40 to 60 cm.

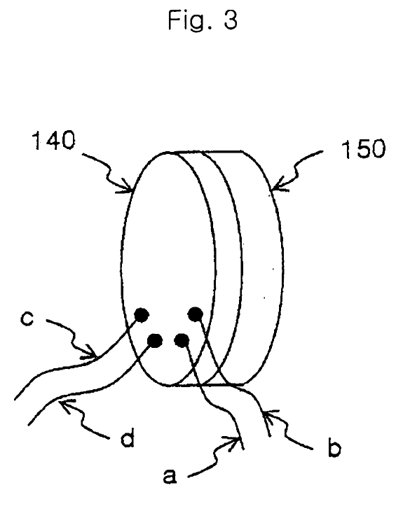

FIG. 3 is a perspective view of an ultrasonic speaker and a ultrasonic drive chip that are implemented as a module. In the module, an ultrasonic drive circuit board 140 for modulating an input audible signal to the ultrasonic band signal and an ultrasonic speaker 150 for outputting an output signal of the ultrasonic drive circuit board 140 to an outside can be integratedly implemented.

Additionally, the ultrasonic drive circuit board 140 is provided with a signal input line a and a signal ground line b for receiving an input of an external signal, and a power supply line c and a power ground line d for receiving a power for driving.

For reference, the module in which the ultrasonic drive circuit board 140 and the ultrasonic speaker 150 are integratedly implemented has a similar size and thickness to those of the speaker used in the conventional mobile communication terminal.

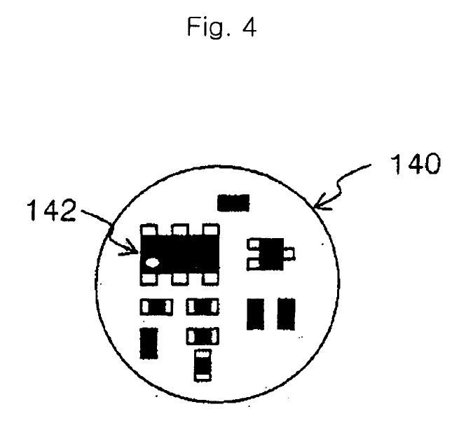

FIG. 4 is a view schematically illustrating the internal construction of the ultrasonic drive circuit board 140 of FIG. 3 on which a drive chip 142 is mounted.

The ultrasonic drive circuit board 140 having the ultrasonic drive chip 142 mounted thereon and the ultrasonic speaker 150 are integratedly implemented and then used in the proposed mobile communication terminal board 100.

Since the ultrasonic speaker system implemented as the integrated module has the similar shape, size and use to those of the existing speaker, it can be easily adopted in the existing mobile communication terminal without any particular modifications.

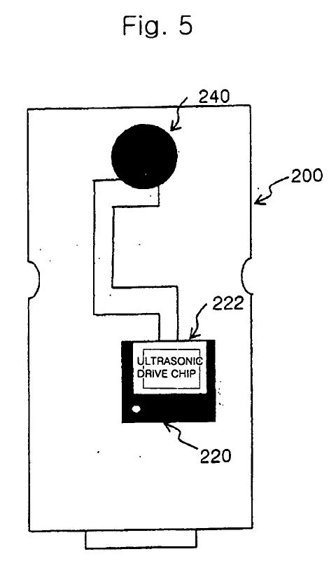

FIG. 5 is a conceptual view illustrating the construction of a mobile communication terminal board having an ultrasonic micro speaker and a baseband chip having a drive circuit for driving the speaker according to a second embodiment of the present invention. As illustrated in FIG. 5, the ultrasonic drive chip 222 is integrated onto the baseband chip 220 in the form of a hardware block to drive the ultrasonic speaker 240.

In comparison to the mobile communication terminal board of FIG. 1 according to the first embodiment of the present invention, the mobile communication terminal board 200 of FIG. 5 is constructed in a manner that an ultrasonic drive chip 222 is integrated into a baseband chip 220 as a hardware block to drive the subminiature ultrasonic speaker 240.

By integrating the ultrasonic drive chip 222 onto the baseband chip 220 as described above, the ultrasonic speaker system can be miniaturized with its power consumption and manufacturing cost reduced.

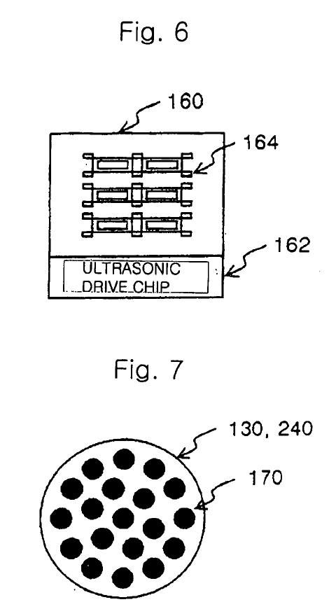

FIG. 6 is a view illustrating an ultrasonic drive chip and an ultrasonic speaker integrated into a semiconductor chip. Referring to FIG. 6, an ultrasonic speaker 164 implemented by an MEMS (Micro Electro Mechanical System) technique and an ultrasonic drive chip 162 are integrated onto one semiconductor chip 160, which is called an USOC (Ultrasonic Speaker On a Chip).

By integrating the ultrasonic drive chip 162 and the ultrasonic speaker 164 onto one chip using a semiconductor fabricating technique as described above, the ultrasonic speaker system can more easily be miniaturized with its power consumption greatly reduced.

This ultrasonic speaker system can be used in the proposed mobile communication terminal boards 100 and 200 of FIGS. 1 and 5.

Now, the miniaturization of the speaker according to the present invention implemented using various techniques so that the speaker can be used in the mobile communication terminal will be explained.

FIG. 7 is a conceptual view illustrating the structure of the ultrasonic speaker 130 or 240 of FIGS. 1 to 5 implemented as a piezoelectric element. In FIG. 7, a plurality of ultrasonic transducers are arranged to form the piezoelectric element.

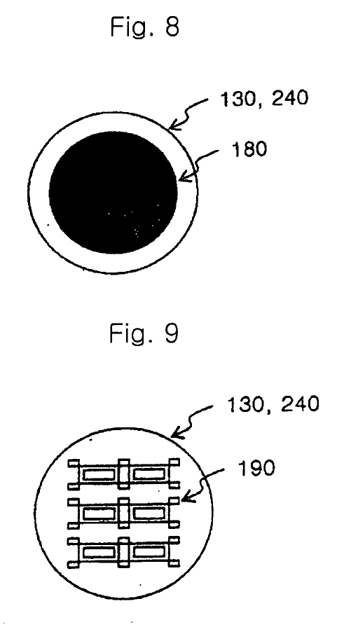

FIG. 8 is a view illustrating the structure of the ultrasonic speaker 130 or 240 of FIGS. 1 to 5 implemented as a thin film type. In FIG. 8, the ultrasonic speaker 130 or 240 is implemented through an ultrasonic transducer 180 using a PVDF (polyvinylidene difluoride) film type piezoelectric element.

According to the above-described ultrasonic speaker, low power consumption can be achieved.

FIG. 9 is a view illustrating the ultrasonic speaker 130 or 240 of FIGS. 1 to 5 implemented using an MEMS technique. In FIG. 9, the ultrasonic speaker is implemented through an ultrasonic transducer 190 implemented according to the MEMS technique.

In the case of implementing the ultrasonic speaker through the ultrasonic transducer implemented according to the MEMS technique, a high-efficient and a small-sized ultrasonic speaker can be produced.

As described above, in the case in which a user makes a video call using the mobile communication terminal provided with the above-described ultrasonic speaker system, it is not required to prepare a separate device. Also, since the audio signal is modulated to the ultrasonic band signal and the ultrasonic band signal output from the speaker is concentrated on a user's face in the distance of 40 to 60 cm, the output ultrasonic band signal is not audible outside the audible sound field formed by the ultrasonic signal, and thus the noise around the terminal can be prevented and the user's private life protected.

Additionally, the present invention can be used even in the case in which the user listens to a sky-wave broadcast using the mobile communication terminal, and in this case, the noise around the terminal can be prevented and the user's private life protected.

The present invention can also be used in the case of using the mobile communication terminal for the voice call, and in this case, the influence of an electromagnetic wave exerted on a human body can be reduced.

It has been reported that in the case of making a phone call with the mobile communication terminal put to a user's head, the electromagnetic wave generated from the mobile communication terminal directly exerts a bad effect on a user's brain. However, since the strength of the electromagnetic wave is in inverse proportion to the distance, the influence of the electromagnetic wave exerted on the user can greatly be reduced even if the user makes a phone call in a state that the user is apart from the mobile communication terminal only for several dozens of centimeters. Accordingly, since the present invention enables the user to make a phone call, being apart from the mobile communication terminal for about several tens of centimeters, the influence of the electromagnetic wave exerted on the user can greatly be reduced.

In the embodiment of the present invention, although it is exemplified that the power supply unit supplies a power to the ultrasonic drive chip in the mobile communication terminal board, the present invention is not limited thereto because the power supply unit can supply the power not only to ultrasonic drive chip but also to the baseband chip and so on.

### INDUSTRIAL APPLICABILITY

As can be seen from the foregoing, according to the present invention, since the ultrasonic speaker system is used in the mobile communication terminal and the audible sound field is formed within a desired area by modulating the output signal to the ultrasonic band signal, the noise around the terminal is prevented and the user's private life can be protected even when the user makes a video call or listens to a sky-wave broadcast. Also, since the output signal is not fed back, the ultrasonic speaker system is free from the echo phenomenon.

Additionally, since the user can use the mobile communication terminal, being apart from the mobile communication terminal for a specified distance, a disease caused by the electromagnetic wave generated from the mobile communication terminal can be reduced.

While this invention has been described in connection with what is presently considered to be the most practical and preferred embodiment, it is to be understood that the invention is not limited to the disclosed embodiment and the drawings, but, on the contrary, it is intended to cover various modifications and variations within the spirit and scope of the appended claims.

1. A mobile communication terminal board comprising:
a baseband chip for processing audio data;
an ultrasonic drive chip for receiving and modulating a signal output from the baseband chip to an ultrasonic band signal; and
an ultrasonic speaker for outputting the ultrasonic signal output from the ultrasonic drive chip to an outside.

2. The mobile communication terminal board as claimed in claim 1, wherein the ultrasonic drive chip and the ultrasonic speaker are implemented and installed as an integrated module.

3. The mobile communication terminal board as claimed in claim 1, wherein the ultrasonic speaker is implemented by a plurality of thin film type ultrasonic transducers.

4. The mobile communication terminal board as claimed in claim 1, wherein the ultrasonic speaker is an ultrasonic transducer using a PVDF (polyvinylidene difluoride) film type piezoelectric element.

5. The mobile communication terminal board as claimed in claim 1, wherein the ultrasonic speaker is implemented through an MEMS (Micro Electro Mechanical System) technique.

6. The mobile communication terminal board as claimed in claim 5, wherein the ultrasonic speaker and the ultrasonic drive chip are implemented as one semiconductor chip.

7. The mobile communication terminal board as claimed in claim 1, wherein the ultrasonic drive chip comprises:
a preprocessing unit for receiving audio data output from the baseband chip and performing a band compensation and distortion compensation of the received audio data;
a carrier generation unit for generating a carrier of an ultrasonic band;
a modulation unit for modulating an output signal of the preprocessing unit to the ultrasonic band signal using the carrier; and
an ultrasonic amplifying unit for amplifying an output signal of the modulation unit.

8. A mobile communication terminal board comprising:
an ultrasonic speaker for outputting a signal modulated to an ultrasonic band; and
a baseband chip, integratedly provided with an ultrasonic drive chip for driving the ultrasonic speaker, for processing audio data.

9. The mobile communication terminal board as claimed in claim 8, wherein the ultrasonic speaker is implemented by a plurality of thin film type ultrasonic transducers.

10. The mobile communication terminal board as claimed in claim 8, wherein the ultrasonic speaker is an ultrasonic transducer using a PVDF (polyvinylidene difluoride) film type piezoelectric element.

11. The mobile communication terminal board as claimed in claim 8, wherein the ultrasonic speaker is implemented through an MEMS (Micro Electro Mechanical System) technique.

12. The mobile communication terminal board as claimed in claim 11, wherein the ultrasonic speaker and the ultrasonic drive chip are implemented as one semiconductor chip.

13. The mobile communication terminal board as claimed in claim 8, wherein the ultrasonic drive chip comprises:
a preprocessing unit for receiving audio data output from the baseband chip and performing a band compensation and distortion compensation of the received audio data;
a carrier generation unit for generating a carrier of an ultrasonic band;
a modulation unit for modulating an output signal of the preprocessing unit to the ultrasonic band signal using the carrier; and
an ultrasonic amplifying unit for amplifying an output signal of the modulation unit.
